(19) United States
(12) Patent Application Publication
(10) Pub. No.: US 2011/0300788 A1
(43) Pub. Date: Dec. 8, 2011

(54) Vertical Exhaust Duct

(75) Inventor: Jack E. Caveney, North Palm Beach, FL (US)

(73) Assignee: PANDUIT CORP., Tinley Park, IL (US)

(21) Appl. No.: 13/151,738

(22) Filed: Jun. 2, 2011

Related U.S. Application Data
(60) Provisional application No. 61/351,155, filed on Jun. 3, 2010.

(51) Int. Cl. H05K 7/20

(52) U.S. Cl. 454/184

(57) ABSTRACT

Certain embodiments of the present invention provide a thermal management system. The thermal management system includes a first cabinet, a second cabinet positioned adjacent the first cabinet, and a multi-cabinet vertical exhaust duct positioned above the first cabinet and the second cabinet. The multi-cabinet vertical exhaust duct includes a shared exhaust plenum. The shared exhaust plenum is in fluid communication with the first cabinet and the second cabinet such that the shared exhaust plenum receives hot air exhausted from electronic equipment in the first cabinet and the second cabinet.

### CROSS REFERENCE TO RELATED APPLICATIONS

This application claims priority to U.S. Provisional Patent Application No. 61/351,155, filed on Jun. 3, 2010, which is incorporated by reference in its entirety.

### BACKGROUND OF THE INVENTION

The present invention relates to a vertical exhaust duct for a network cabinet. More particularly, the present invention relates to a vertical exhaust duct for a network cabinet including one or more of the following features: (1) leveling; (2) ganging; (3) insulation; and (4) multi-cabinet coverage.

### SUMMARY OF THE INVENTION

Certain embodiments of the present invention provide a thermal management system. The thermal management system includes a first cabinet, a second cabinet positioned adjacent the first cabinet, and a multi-cabinet vertical exhaust duct positioned above the first cabinet and the second cabinet. The multi-cabinet vertical exhaust duct includes a shared exhaust plenum. The shared exhaust plenum is in fluid communication with the first cabinet and the second cabinet such that the shared exhaust plenum receives hot air exhausted from electronic equipment in the first cabinet and the second cabinet.

### BRIEF DESCRIPTION OF THE DRAWINGS

FIG. 1 is a perspective view of a vertical exhaust duct for a network cabinet according to an embodiment of the present invention;

FIG. 2 is a partial side cross-sectional view of the vertical exhaust duct of FIG. 1, showing the leveling features in detail 2 of FIG. 1;

FIG. 3 is a front perspective view of the vertical exhaust duct of FIG. 1, showing only a portion of the vertical exhaust duct;

FIG. 4 is an enlarged front perspective view of the vertical exhaust duct of FIG. 3, showing the leveling features in detail 4 of FIG. 3;

FIG. 5 is an enlarged front perspective view of the vertical exhaust duct of FIG. 1, showing the ganging features;

FIG. 6 is an enlarged front view of the vertical exhaust duct of FIG. 5, showing the ganging features;

FIG. 7 is an enlarged front perspective view of the vertical exhaust duct of FIG. 5, showing only a portion of the ganging features;

FIGS. 8-10 shows an exemplary installation sequence for ganging adjacent vertical exhaust ducts according to an embodiment of the present invention;

FIG. 11 is a front perspective view of an insulated vertical exhaust duct according to an embodiment of the present invention;

FIG. 12 is a partial side cross-sectional view of the vertical exhaust duct of FIG. 11;

FIG. 13 is a perspective view of a multi-cabinet vertical exhaust duct according to an embodiment of the present invention;

FIG. 14. is a front view of 1 84-inch wide vertical exhaust duct for 3 28-inch wide network cabinets according to an embodiment of the present invention;

FIG. 15 is a front view of 1 96-inch wide vertical exhaust duct for 3 32-inch wide network cabinets according to an embodiment of the present invention; and

FIG. 16 is a front view of 1 96-inch wide vertical exhaust duct for 4 24-inch wide network cabinets according to an embodiment of the present invention.

### DETAILED DESCRIPTION

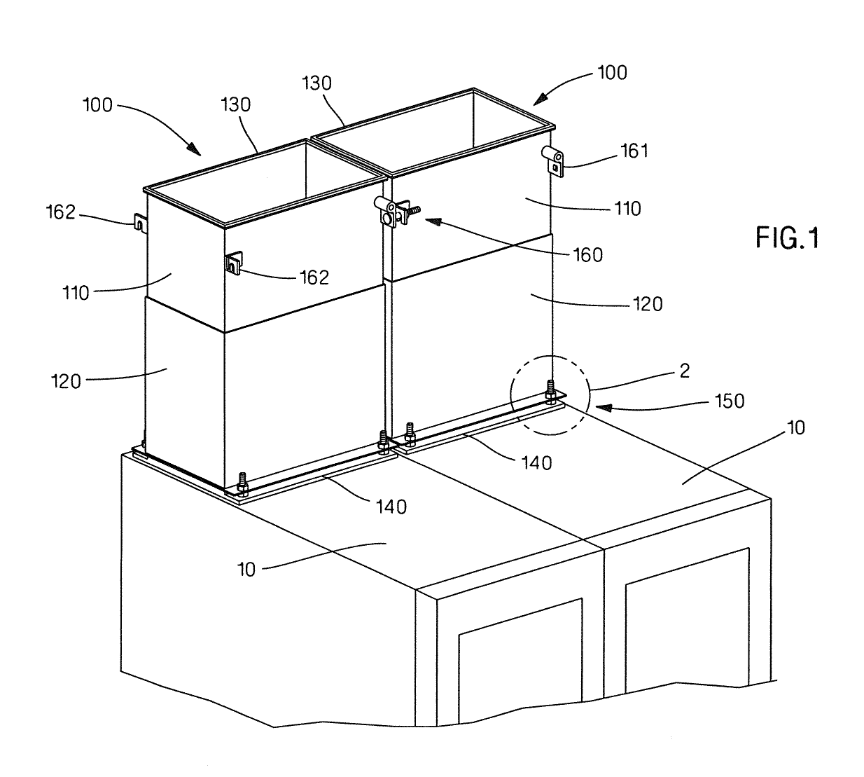

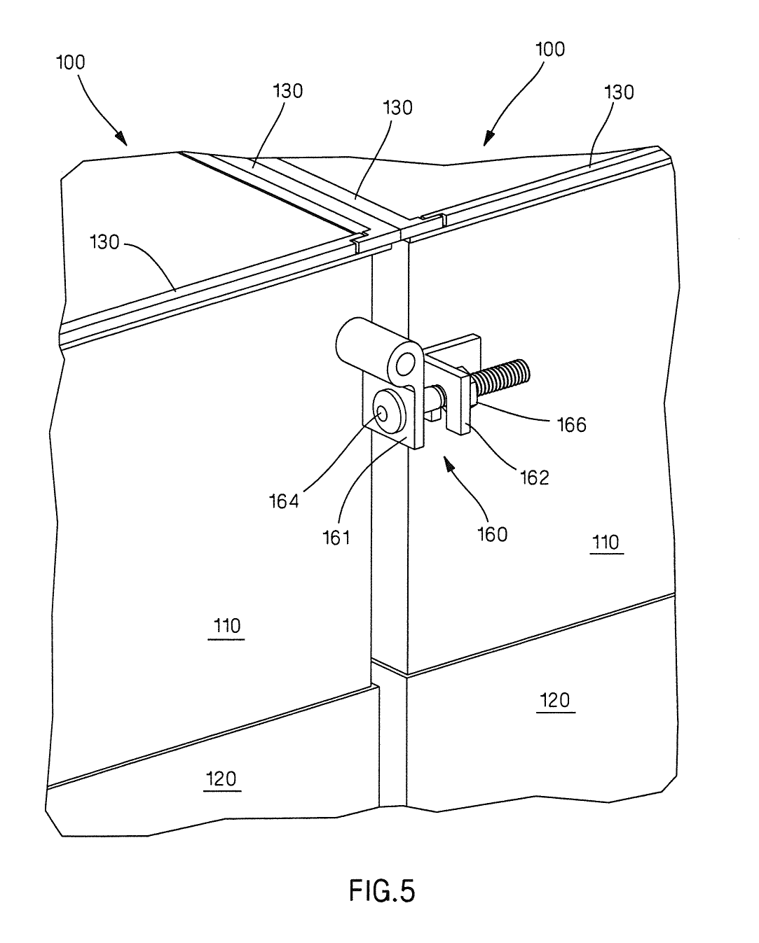

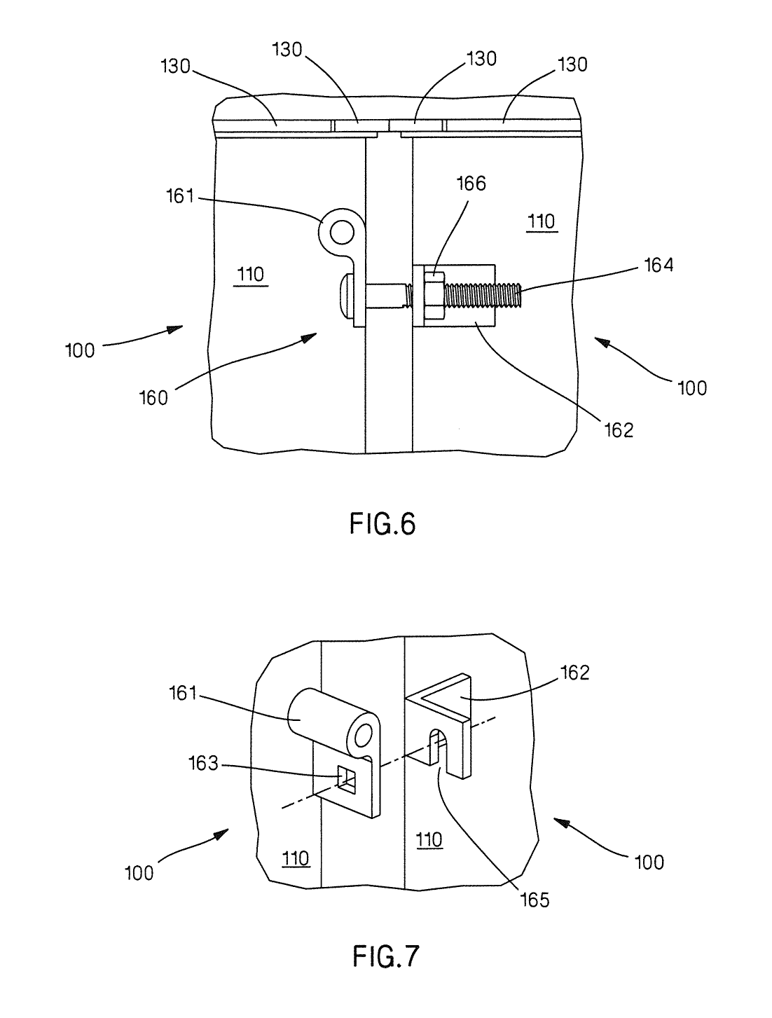

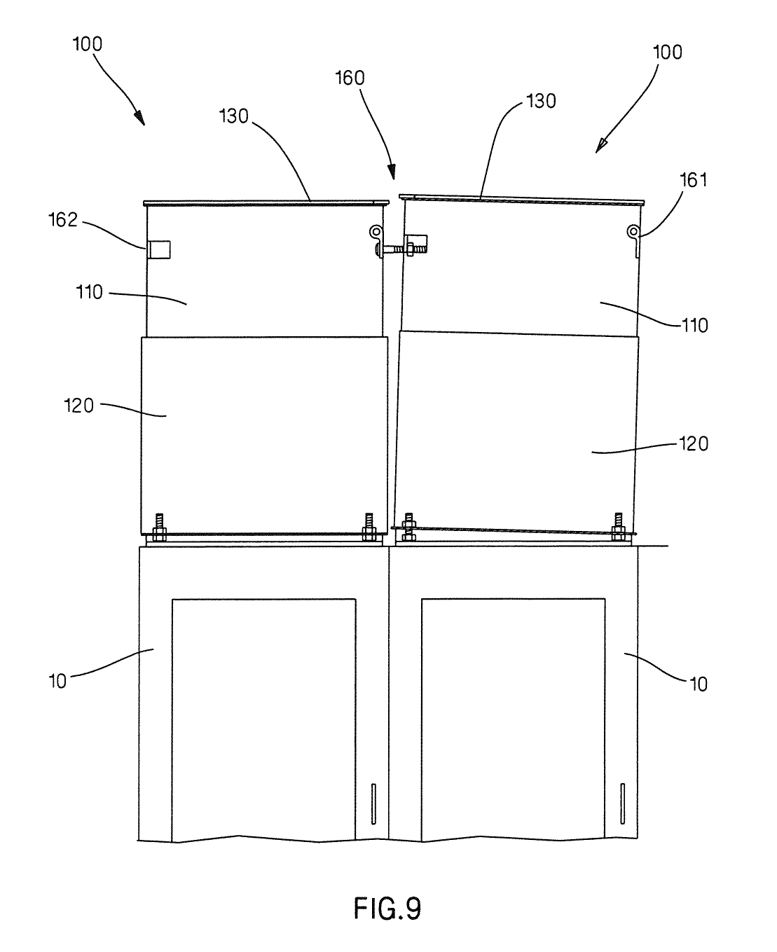

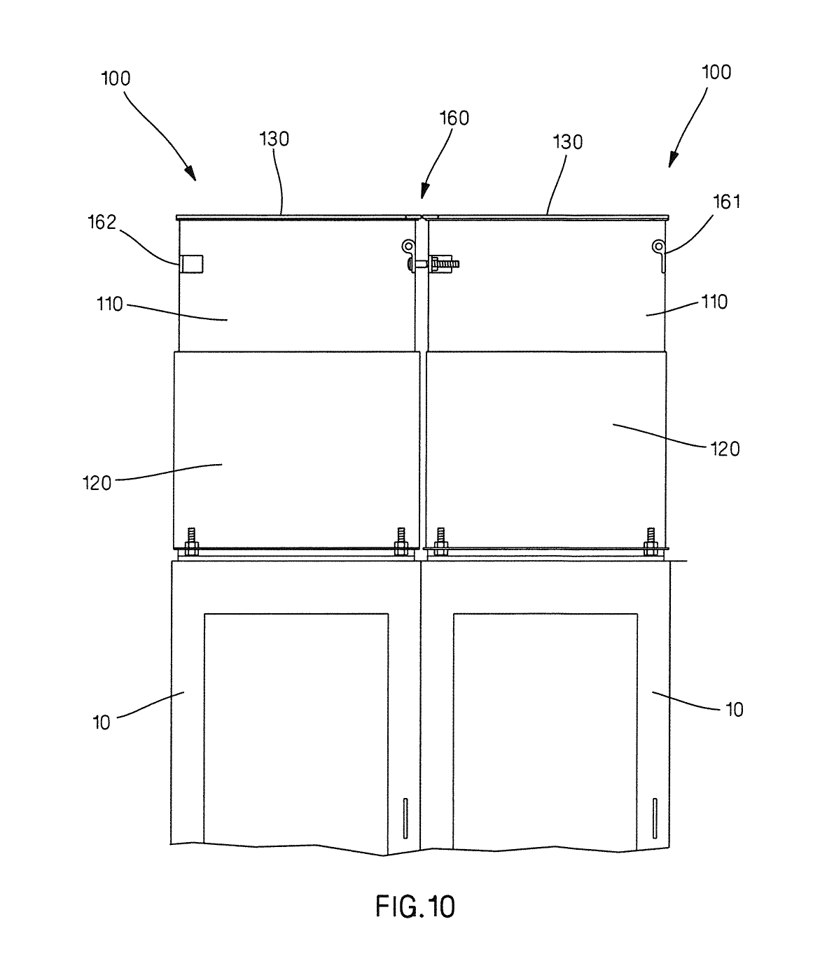

FIGS. 1-16 illustrate a vertical exhaust duct 100 for one or more network cabinets 10 according to several embodiments of the present invention.

The vertical exhaust duct 100 is similar to the vertical exhaust ducts disclosed in U.S. patent application Ser. No. 12/731,877 and U.S. Provisional Patent Application Nos. 61/184,464 and 61/222,528, each of which is incorporated by reference in its entirety.

As shown in FIG. 1, the vertical exhaust duct 100 includes a top duct section 110 and a bottom duct section 120. The top duct section 110 is positioned inside of the bottom duct section 120 and extends to a desired height. A locking system (not shown), such as the pawl locking system disclosed in U.S. patent application Ser. No. 12/731,877, locks the vertical exhaust duct 100 at the desired height. A seal 130, such as the adjustable foam seal disclosed in U.S. Provisional Patent Application Nos. 61/184,464 and 61/222,528, seals the gap between the vertical exhaust duct 100 and the exhaust air plenum or ceiling in the data center room, as well as the gaps between the vertical exhaust duct 100 and adjacent vertical exhaust ducts 100.

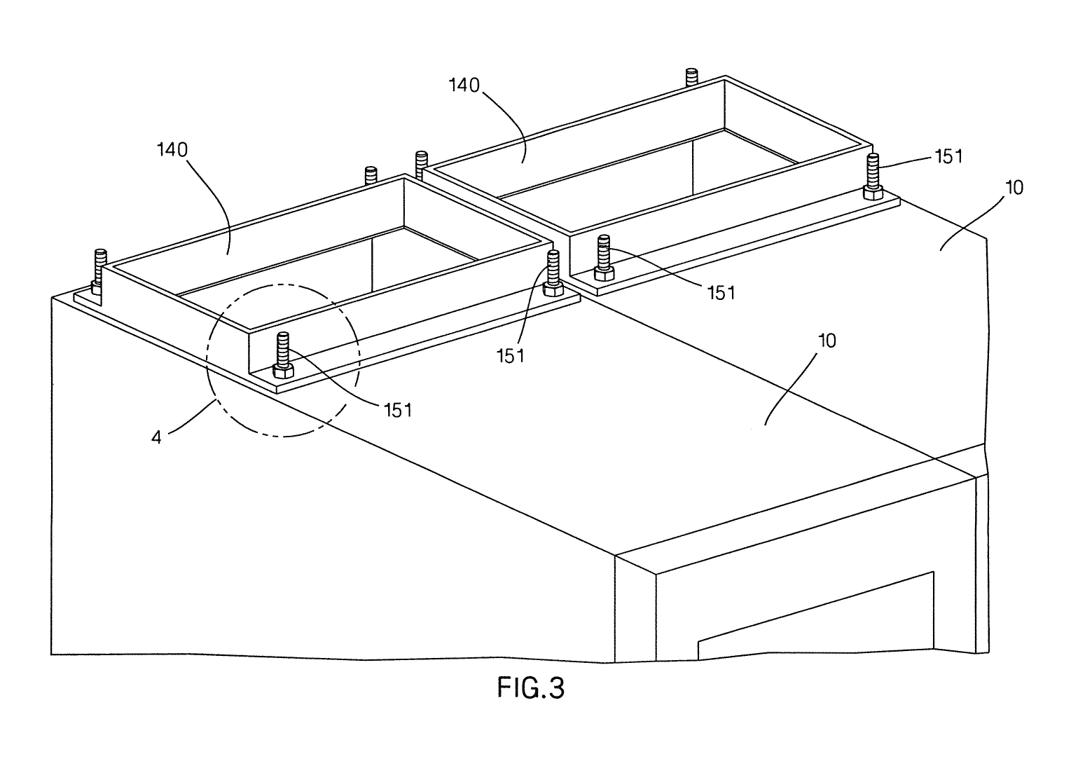

As shown in FIG. 3, the vertical exhaust duct 100 includes a base 140 for mounting the vertical exhaust duct 100 to the network cabinet 10. The bottom duct section 120 is connected to the base 140 and the base 140 is connected to the network cabinet 10. Alternatively, the bottom duct section 120 is connected directly to the network cabinet 10, potentially eliminating the need for the base 140.

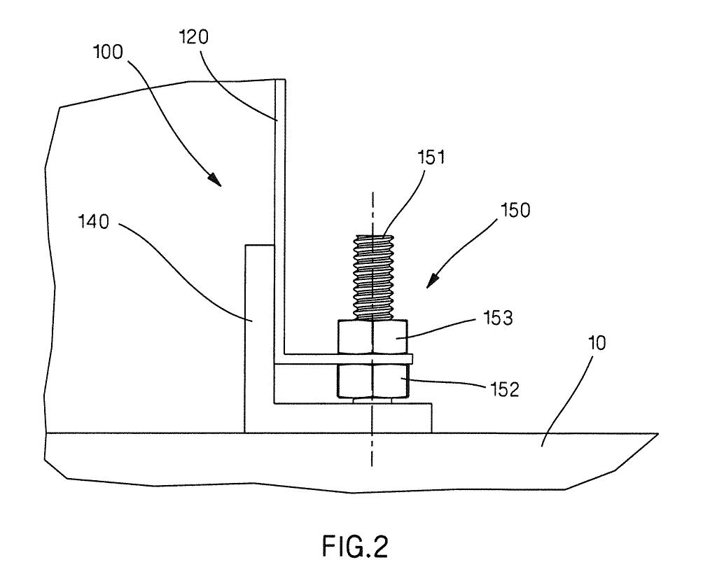

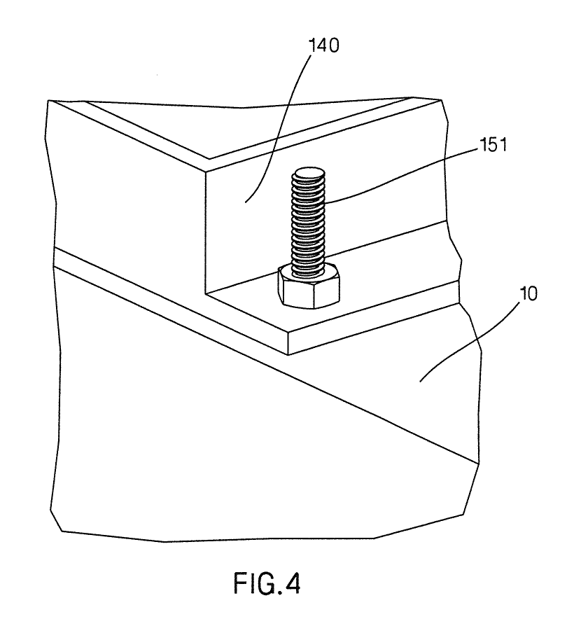

In certain embodiments of the present invention, the vertical exhaust duct 100 includes one or more leveling features 150 for leveling the vertical exhaust duct 100. For example, as shown in FIGS. 2 and 4, the base 140 includes a stud 151, such as a PEM stud. Alternatively, the network cabinet 10 includes the stud 151 when the bottom duct section 120 is connected directly to the network cabinet 10. The bottom duct section 120 includes an opening (not shown) for receiving the stud 151. A nut 152, such as a nylock nut, is for leveling the bottom duct section 120, and a nut 153, such as a jam nut, is for securing the bottom duct section 120 to the base 140, preferably after the vertical exhaust duct 100 has been leveled.

In certain embodiments of the present invention, the vertical exhaust duct 100 includes one or more ganging features 160 for ganging the vertical exhaust duct 100. For example, as shown in FIGS. 1 and 5-7, the top duct section 110 includes a pivot bracket 161 and a fixed bracket 162. The pivot bracket 161 of the vertical exhaust duct 100 and the fixed bracket 162 of the adjacent vertical exhaust duct 100 are aligned. The pivot bracket 161 includes an opening 163 for receiving a bolt 164. Preferably, the bolt 164 is secured to the pivot bracket 161. The fixed bracket 162 includes a slot 165 for receiving the bolt 164 when the pivot bracket 161 is rotated into alignment with the fixed bracket 162. A nut 166, such as a nylock nut, is for securing the bolt 164 in the slot 165, thereby securing the vertical exhaust duct 100 to the adjacent vertical exhaust duct 100.

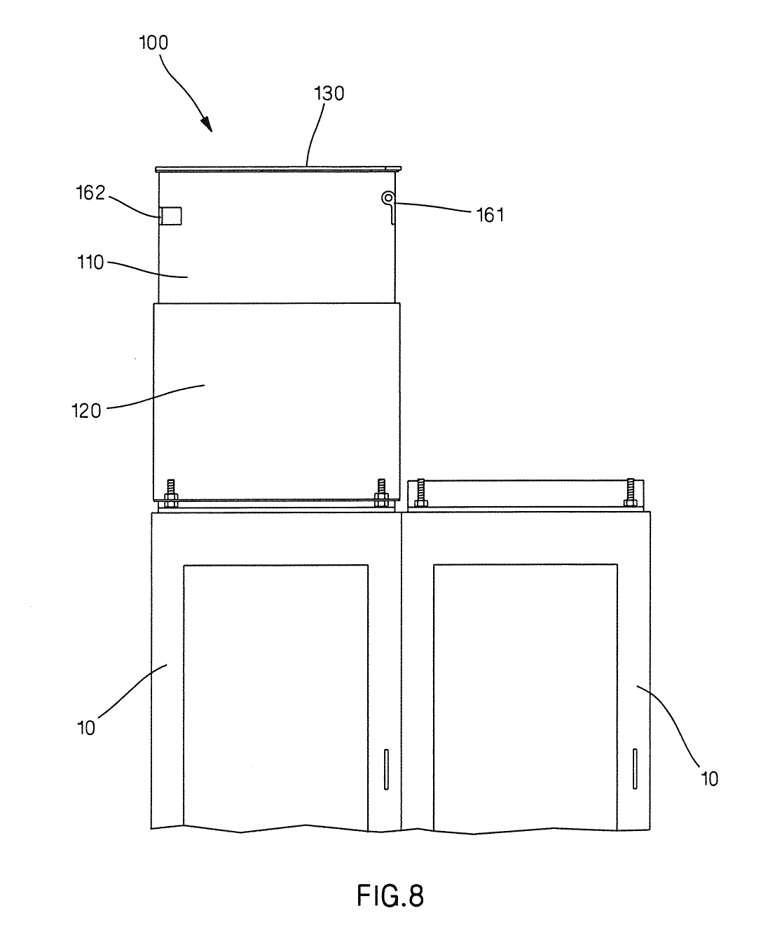

An example of an installation sequence for ganging adjacent vertical exhaust ducts 100 is shown in FIGS. 8-10.

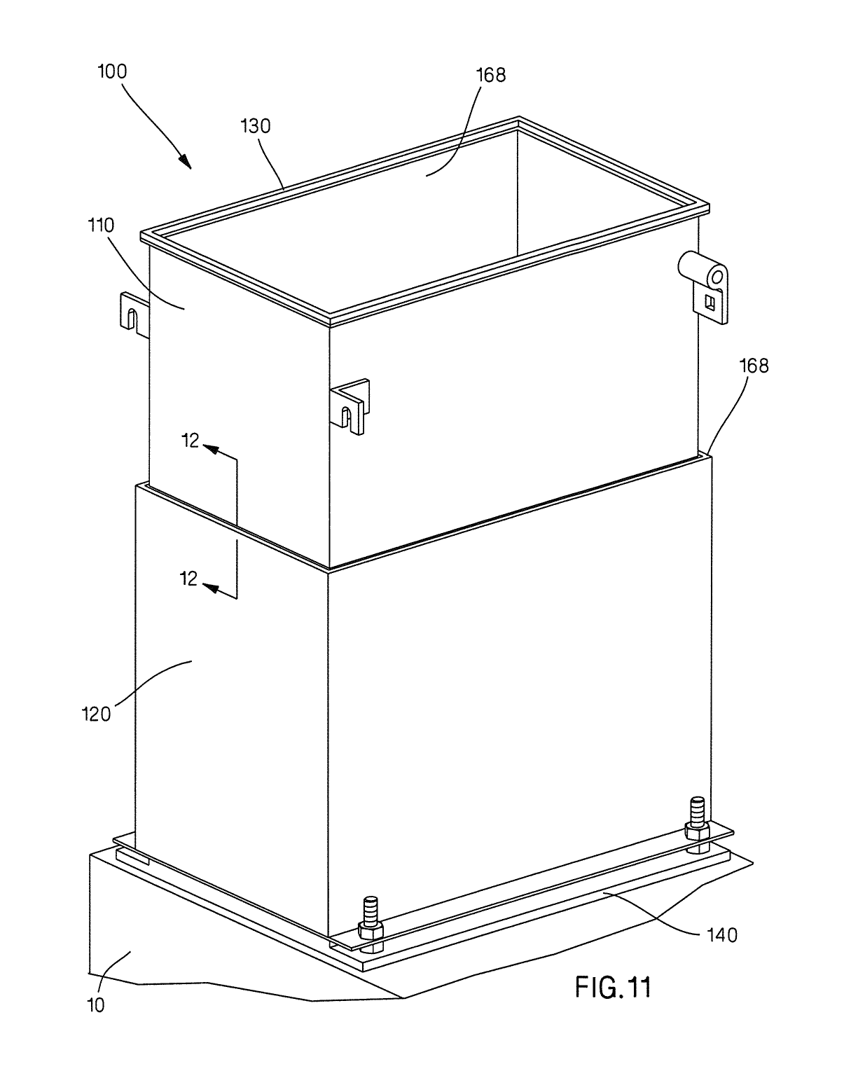

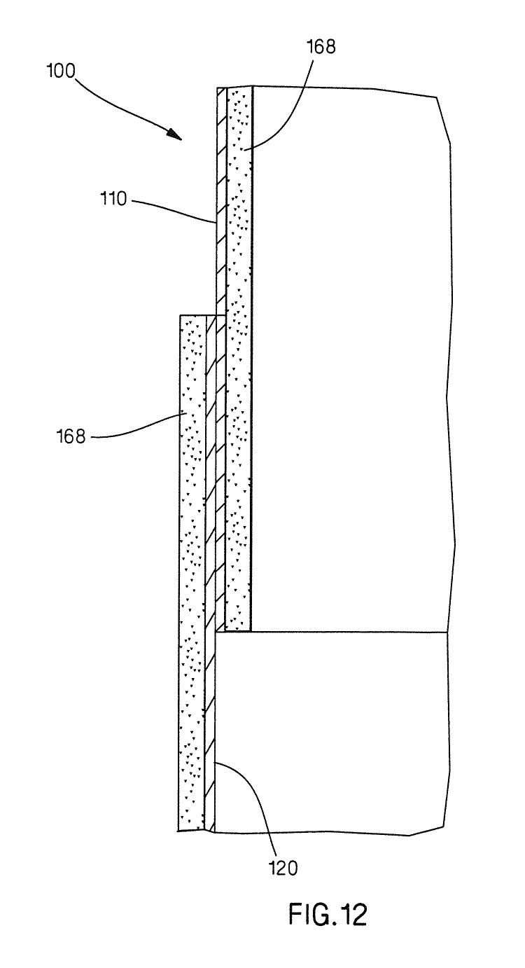

Certain embodiments of the present invention provide an insulated vertical exhaust duct 100. For example, as shown in FIG. 11 and FIG. 12, insulation 160, such as acoustic, thermal, and/or other types of insulation, is positioned inside of the top duct section 110 and outside of the bottom duct section 120.

Certain embodiments of the present invention provide an insulated network cabinet 10, which is similar to the insulated vertical exhaust duct 100 of FIG. 11 and FIG. 12.

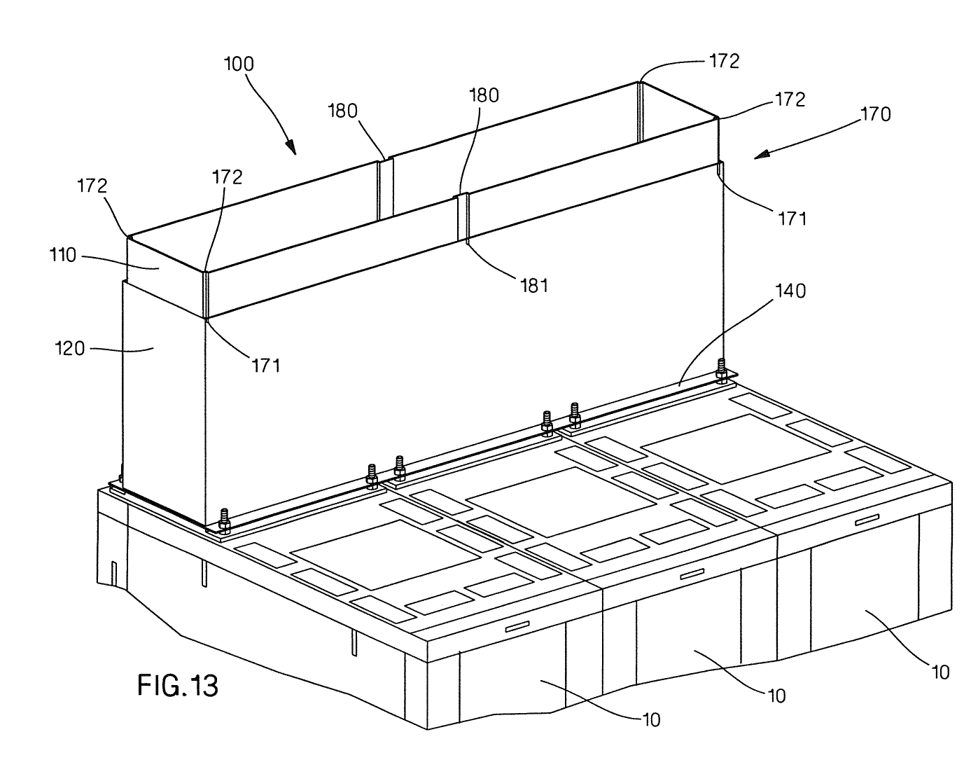

Certain embodiments of the present invention provide a multi-cabinet vertical exhaust duct. For example, as shown in FIG. 13, 1 vertical exhaust duct 100 covers 3 network cabinets 10. The vertical exhaust duct 100 includes a pawl locking system 170, including pawls 171 and guides 172, but it is likewise contemplated that the vertical exhaust duct 100 includes other types of locking systems, such as the locking systems disclosed in U.S. patent application Ser. Nos. 12/731,877 and U.S. Provisional Patent Application Nos. 61/184,464 and 61/222,528. Additionally, the vertical exhaust duct 100 includes optional center guide channels or stiffeners 180 for accommodating additional pawls 181 and/or providing additional stiffness to the vertical exhaust duct 100. Preferably, the vertical exhaust duct 100 is made of aluminum to reduce weight and aid in installation, but it is likewise contemplated that the vertical exhaust duct 100 is made of stainless steel or other such materials.

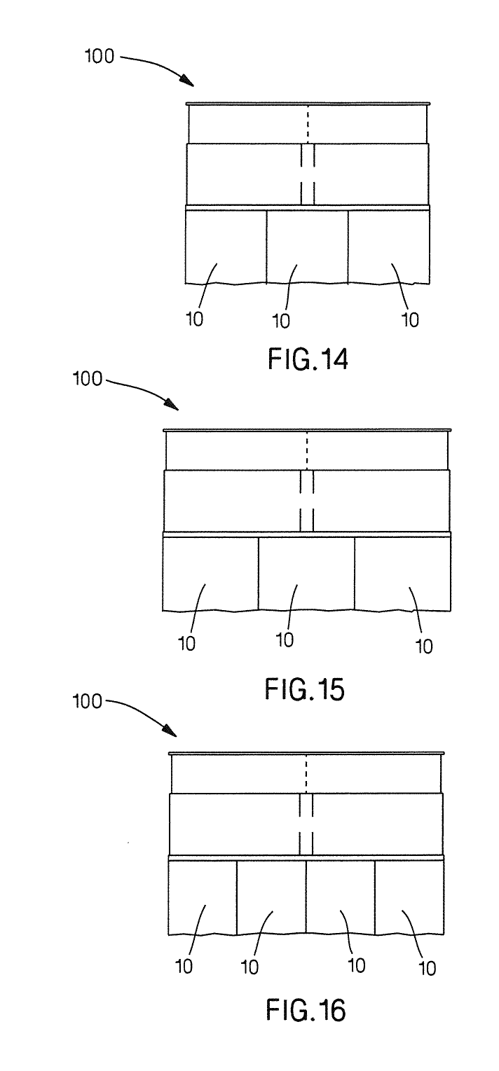

As shown in FIG. 14, 1 84-inch wide vertical exhaust duct 100 accommodates 3 28-inch wide network cabinets 10. Alternatively, as shown in FIG. 15 and FIG. 16, 1 96-inch wide vertical exhaust duct 100 accommodates 3 32-inch wide network cabinets 10 (FIG. 15) or 4 24-inch wide network cabinets 10 (FIG. 16).

While this invention has been described in conjunction with the exemplary embodiments outlined above, various alternatives, modifications, variations, and/or improvements, whether known or presently unforeseen, may become apparent. Accordingly, the exemplary embodiments of the invention as set forth above are intended to be illustrative, not limiting. Various changes may be made without departing from the spirit and scope of the invention.

1. A thermal management system comprising:
a first cabinet;
a second cabinet positioned adjacent the first cabinet; and
a multi-cabinet vertical exhaust duct positioned above the first cabinet and the second cabinet, the multi-cabinet vertical exhaust duct having a shared exhaust plenum, the shared exhaust plenum in fluid communication with the first cabinet and the second cabinet such that the shared exhaust plenum receives hot air exhausted from electronic equipment in the first cabinet and the second cabinet.

2. The multi-cabinet vertical exhaust duct system of claim 1, wherein the multi-cabinet vertical exhaust duct includes a first duct section and a second duct section slidably connected to the first duct section and extendable to a desired height above the first duct section.

3. The multi-cabinet vertical exhaust duct system of claim 2, wherein at least one of the first duct section and the second duct section includes at least one fastener for securing the second duct section to the first duct section at the desired height.

4. The multi-cabinet vertical exhaust duct system of claim 3, wherein the at least one fastener includes a pawl.

5. The multi-cabinet vertical exhaust duct system of claim 4, wherein the at least one of the first duct section and the second duct section includes at least one guide channel for receiving the pawl.

6. The multi-cabinet vertical exhaust duct system of claim 5, wherein the at least one guide channel is disposed adjacent one of the opposing sides of the multi-cabinet vertical exhaust duct.

7. The multi-cabinet vertical exhaust duct system of claim 5, wherein the at least one guide channel is disposed midway between opposing sides of the multi-cabinet vertical exhaust duct.

8. The multi-cabinet vertical exhaust duct system of claim 1, wherein the multi-channel vertical exhaust duct includes at least one guide channel for stiffening the multi-cabinet vertical exhaust duct.

9. The multi-cabinet vertical exhaust duct system of claim 1, wherein the multi-cabinet vertical exhaust duct is mounted to a top portion of each of the first cabinet and the second cabinet.

10. The multi-cabinet vertical exhaust duct system of claim 1, wherein the multi-cabinet vertical exhaust duct is made of aluminum.

11. The multi-cabinet vertical exhaust duct system of claim 1, wherein the multi-cabinet vertical exhaust duct is made of stainless steel.

12. The multi-cabinet vertical exhaust duct system of claim 1, wherein the width of the shared exhaust plenum is greater than the width of each of the first cabinet and the second cabinet.

13. The multi-cabinet vertical exhaust duct system of claim 12, wherein the width of the first cabinet is the same as the width of the second cabinet.

14. The multi-cabinet vertical exhaust duct system of claim 12, wherein the width of the first cabinet is less than the width of the second cabinet.

15. The multi-cabinet vertical exhaust duct system of claim 1, further comprising a third cabinet positioned adjacent the second cabinet, the multi-cabinet vertical exhaust duct positioned above the third cabinet, the shared exhaust plenum in fluid communication with the third cabinet such that the shared exhaust plenum receives hot air exhausted from the third cabinet.

16. The multi-cabinet vertical exhaust duct system of claim 15, wherein the width of each of the first cabinet, the second cabinet, and the third cabinet is about 28 inches and the width of the multi-cabinet vertical exhaust duct is about 84 inches.

17. The multi-cabinet vertical exhaust duct system of claim 15, wherein the width of each of the first cabinet, the second cabinet, and the third cabinet is about 32 inches and the width of the multi-cabinet vertical exhaust duct is about 96 inches.

18. The multi-cabinet vertical exhaust duct system of claim 15, further comprising a fourth cabinet positioned adjacent the third cabinet, the multi-cabinet vertical exhaust duct positioned above the fourth cabinet, the shared exhaust plenum in fluid communication with the fourth cabinet such that the shared exhaust plenum receives hot air exhausted from the fourth cabinet.

19. The multi-cabinet vertical exhaust duct system of claim 18, wherein the width of each of the first cabinet, the second cabinet, the third cabinet, and the fourth cabinet is about 24 inches and the width of the multi-cabinet vertical exhaust duct is about 96 inches.

20. A thermal management method comprising:
positioning a first cabinet;
positioning a second cabinet adjacent the first cabinet; and
positioning a multi-cabinet vertical exhaust duct above the first cabinet and the second cabinet, the multi-cabinet vertical exhaust duct having a shared exhaust plenum, the shared exhaust plenum in fluid communication with the first cabinet and the second cabinet such that the shared exhaust plenum receives hot air exhausted from electronic equipment in the first cabinet and the second cabinet.
